(19) United States
(12) Patent Application Publication
(10) Pub. No.: US 2013/0244183 A1
(43) Pub. Date: Sep. 19, 2013

(54) PROCESS FOR PRODUCING INK JET RECORDING HEAD

(71) Applicant: CANON KABUSHIKI KAISHA, Tokyo (JP)

(72) Inventors: Shoji Shiba, Yokohama-shi (JP); Isamu Horiuchi, Yokohama-shi (JP)

(73) Assignee: CANON KABUSHIKI KAISHA, Tokyo (JP)

(21) Appl. No.: 13/770,131

(22) Filed: Feb. 19, 2013

(30) Foreign Application Priority Data
Mar. 13, 2012 (JP) 2012-055843

(51) Int. Cl. G03F 7/20

(52) U.S. Cl. CPC G03F 7/2022
USPC 430/320

(57) ABSTRACT

Provided is a process for producing an ink jet recording head, including: forming, on a substrate, a resin composition layer including a cationically polymerizable epoxy resin composition containing a specific compound; carrying out a first pattern exposure and a first heat treatment at the resin composition layer; carrying out a second pattern exposure and a second heat treatment at an unexposed portion of the resin composition layer; and, removing an unexposed portion in the first pattern exposure and in the second pattern exposure by a development treatment, thereby forming an ejection orifice for ejecting ink and an ejection portion having a taper shape in which an inner diameter reduces toward the ejection orifice.

### BACKGROUND OF THE INVENTION

1. Field of the Invention

The present invention relates to a process for producing an ink jet recording head which performs recording by ejecting ink onto a recording medium.

2. Description of the Related Art

An ink jet recording head generally includes a flow path, an energy-generating element provided in part of the flow path, for generating energy for ejecting ink, a minute ejection orifice for ejecting ink, and an ejection portion communicating to the ejection orifice.

In recent years, the diameter of an ejection orifice of an ink jet recording head tends to become smaller and smaller for reasons of necessity to eject a minute liquid droplet. However, the following problems may arise. For example, in a minute ejection orifice and an ejection portion communicating thereto, the flow resistance of ink becomes high and thus there are cases in which ink is difficult to eject. Further, this may be a cause of slowing of recovery (ink refill) speed. In addition, when the viscosity of ink increases due to evaporation of the ink from the ejection orifice during standby, there are cases in which ejection failure may be caused at an initial stage of ejection.

As a process for solving such problems, there is a process in which, by forming an ejection portion having a so-called taper shape in which the diameter of the ejection portion is reduced toward an ejection orifice, the flow resistance and the evaporation of ink are reduced. As a process for forming an ejection portion having a taper shape by photolithography using a negative photoresist as a material for forming an ejection orifice and the ejection portion, for example, a process disclosed in Japanese Patent No. 4498363 can be applied.

In the above-mentioned process, firstly, first pattern exposure is carried out via a first photomask on a photoresist layer for forming the ejection orifice and the ejection portion. Then, heat treatment (PEB) is carried out to form a concavity in an unexposed portion on the surface of the photoresist layer. Specifically, when cross-linking reaction in an exposed portion proceeds by PEB, a monomer component of the photoresist is transported from the unexposed portion to the exposed portion, which results in reduction of volume of the unexposed portion to form a depression (concavity). After that, second pattern exposure is carried out via a second photomask on the concavity. Then, development is carried out to form the ejection orifice and the ejection portion. In the second pattern exposure, irradiated light is refracted by the concavity, and consequently, the ejection portion having a taper shape can be formed.

### SUMMARY OF THE INVENTION

According to an exemplary embodiment of the present invention, there is provided a process for producing an ink jet recording head, including:

forming, on a substrate, a resin composition layer including a cationically polymerizable epoxy resin composition;

carrying out a first pattern exposure and a first heat treatment at the resin composition layer;

carrying out a second pattern exposure and a second heat treatment at an unexposed portion of the resin composition layer; and

removing an unexposed portion in the first pattern exposure and in the second pattern exposure by a development treatment; and

forming an ejection orifice for ejecting ink and an ejection portion having a taper shape in which inner diameter reduces toward the ejection orifice,

in which the cationically polymerizable epoxy resin composition includes at least:

(A) a multifunctional epoxy resin;

(B) a compound which generates an acid by light irradiation; and

(C) a compound represented by at least one of the following structural formula (1) and the following structural formula (2).

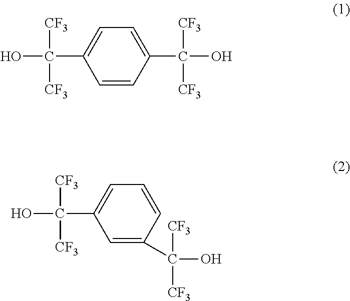 [SMILES: OC(c1ccc(C(O)(C(F)(F)F)C(F)(F)F)cc1)(C(F)(F)F)C(F)(F)F ; OC(c1cccc(C(O)(C(F)(F)F)C(F)(F)F)c1)(C(F)(F)F)C(F)(F)F]

Further features of the present invention will become apparent from the following description of exemplary embodiments with reference to the attached drawings.

### BRIEF DESCRIPTION OF THE DRAWINGS

FIGS. 1A, 1B and 1C are sectional views illustrating the principle for forming an ejection portion having a taper shape.

FIG. 2 is a sectional view illustrating a case in which a diameter φa of a concavity is reduced.

FIG. 3 is a partially cutaway schematic perspective view of an ink jet recording head produced by a process according to the present invention.

FIG. 4 is a perspective view of a substrate used in the process according to the present invention.

FIGS. 5A, 5B, 5C, 5D, 5E, 5F, 5G, 5H and 5I are sectional views illustrating a process according to a first embodiment of the present invention.

FIGS. 6A, 6B, 6C, 6D and 6E are sectional views illustrating a process according to a second embodiment of the present invention.

FIGS. 7A, 7B, 7C, 7D and 7E are sectional views illustrating a process according to a third embodiment of the present invention.

### DESCRIPTION OF THE EMBODIMENTS

It is preferred to reduce a taper angle of a taper shape, that is, to more reduce the diameter of an ejection portion toward an ejection orifice, because evaporation of ink can be inhibited more. However, in the above-mentioned process disclosed in Japanese Patent No. 4498363, the taper angle of a taper shape which can be formed has a limit, and there are cases in which an ejection portion having a taper angle that is small enough to obtain desired performance cannot be obtained.

It is an object of the present invention to provide an ink jet recording head including an ejection portion having a taper shape with a small taper angle.

In a process according to the present invention, a concavity formed in the surface of a photoresist layer functions as a lens, and such a phenomenon that light is refracted at a slanted portion of the lens is applied to the formation of an ejection orifice (ejection portion) of an ink jet recording head.

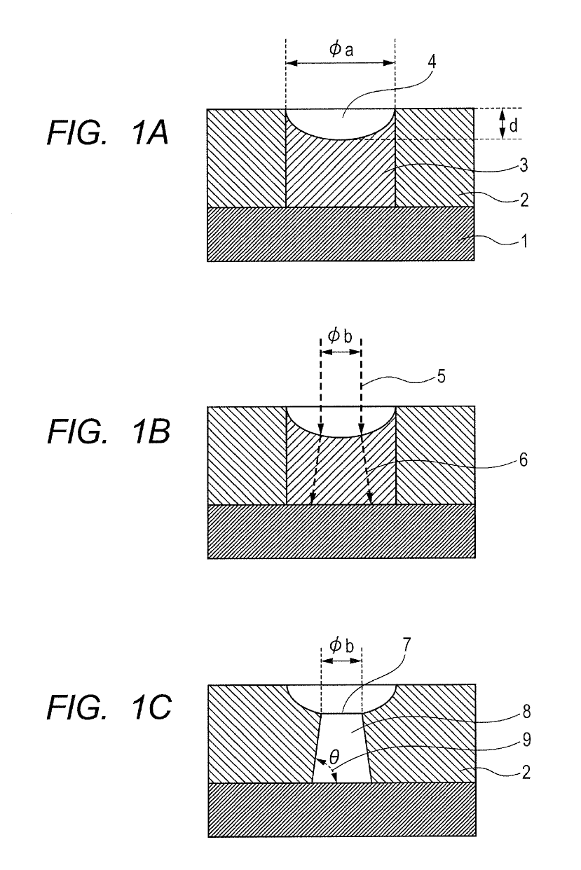

FIGS. 1A to 1C illustrate the principle for forming an ejection portion having a taper shape. FIG. 1A illustrates a state in which, after a first pattern exposure is carried out via a first photomask (not shown) on a photoresist layer applied onto a substrate 1, a first heat treatment (first PEB) is carried out to form, on the surface of the photoresist layer, a concavity 4 having a diameter φa and a depth d. The concavity 4 is surrounded by a cured photoresist layer 2 and an uncured photoresist layer 3 underlies the concavity 4.

FIG. 1B illustrates a state in which a second pattern exposure is carried out via a second photomask (not shown) on the concavity 4 (uncured photoresist layer 3) for forming an ejection orifice having a diameter φb. Light 5 which passes through the second photomask (not shown) is refracted by a slanted portion of the concavity 4 to be refracted light 6 to cure part of the uncured photoresist layer 3. After that, by carrying out a second heat treatment (second PEB) and carrying out a development, there are formed an ejection orifice 7 having the diameter φb and an ejection portion 8 having a taper angle 9 of an angle θ (FIG. 1C).

With reference to FIGS. 1A to 1C, in order to reduce the taper angle 9, it is necessary to refract, to a large extent, the light 5 which passes through the second photomask (not shown). In order to attain this, it is effective to refract the light at a more steeply slanted portion of the concavity 4. The slant of the concavity 4 is formed roughly based on a catenary curve, and thus, there are (1) a process of sufficiently reducing the diameter φa of the concavity 4 with respect to the diameter φb of the ejection orifice 7, and (2) a process of increasing the depth d of the concavity 4.

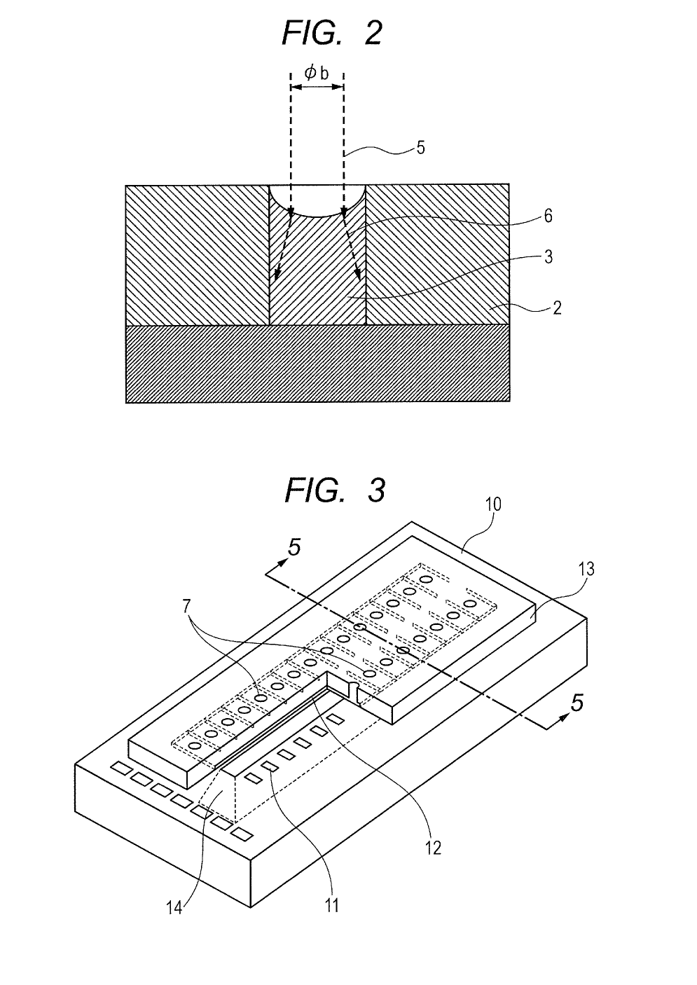

However, in the above-mentioned process (1), as illustrated in FIG. 2, the refracted light 6 interferes with portions which are cured by the first pattern exposure, and thus, the taper shape cannot be formed so as to reach the bottom of the ejection portion 8. Further, the concavity 4 is formed by migration of a monomer component of the photoresist from the unexposed portion to the exposed portion to reduce the volume of the unexposed portion, and thus, the depth d of the concavity 4 greatly depends on the volume (thickness) of the photoresist layer.

According to the present invention, when the ejection portion having a taper shape is formed by photolithography using the photoresist as a material for forming the ejection orifice, by the process (2) of increasing the depth d of the concavity 4, the taper angle can be reduced. Further, by inhibiting evaporation of ink, an ink jet recording head with improved reliability and excellent efficiency of ejecting ink can be provided.

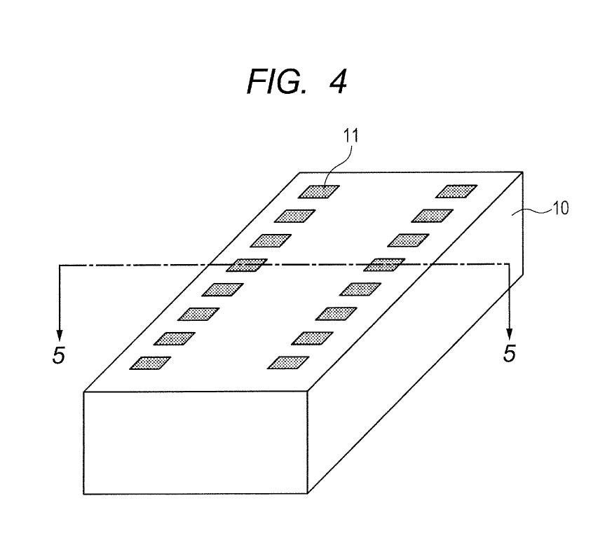

A process for producing an ink jet recording head according to the present invention, which is capable of increasing the depth d of the concavity 4 is described with reference to FIG. 3 to FIG. 7E. FIG. 3 is a partially cutaway schematic perspective view illustrating an exemplary ink jet recording head produced by the process according to the present invention. The ink jet recording head illustrated in FIG. 3 includes a silicon substrate 10 including multiple energy-generating elements 11. As illustrated in FIG. 4, the multiple energy-generating elements 11 are arranged on the silicon substrate 10 at predetermined pitches. The silicon substrate 10 includes an ink flow path 12 for holding ink, ink ejection orifices 7 for ejecting ink, which communicate to the ink flow path 12, and an ink flow path forming layer 13 for forming the ink flow path 12 and the ink ejection orifices 7. Further, an ink supply port 14 for supplying ink to the ink flow path 12 is provided in the silicon substrate 10.

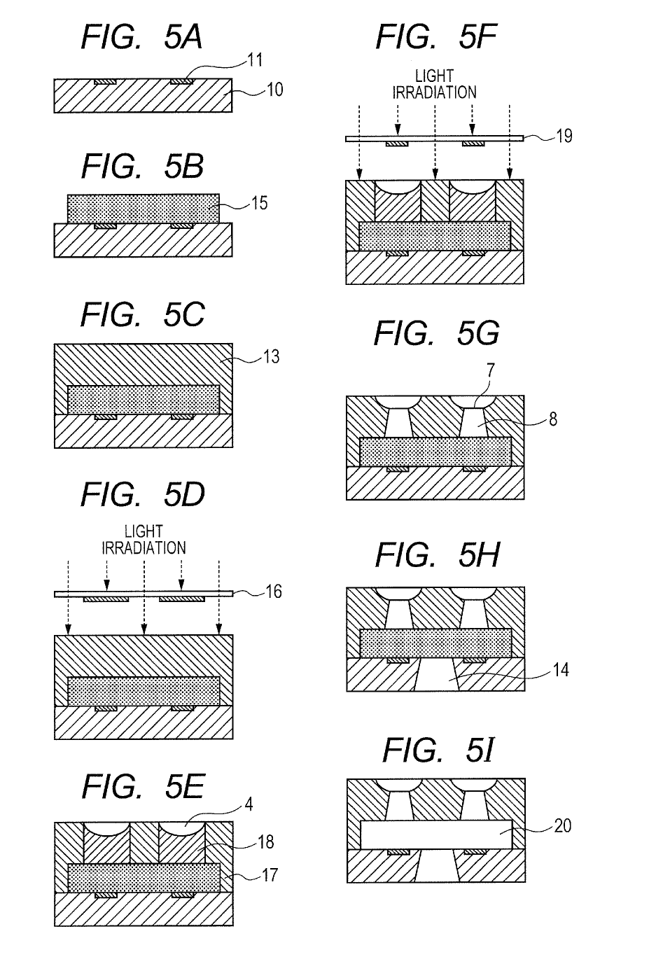

FIG. 5A to FIG. 7E schematically illustrate processes for producing an ink jet recording head according to the present invention as sectional views taken along the line 5-5 of FIG. 3 and FIG. 4. In the following, exemplary embodiments of the present invention are described in detail, but the present invention is not limited thereto.

### First Embodiment

A first embodiment of the present invention is described in the following with reference to FIGS. 5A to 5I. Note that, steps illustrated in FIGS. 5A to 5I are hereinafter referred to as Steps (a) to (i), respectively.

Step (a)

First, the silicon substrate 10 including the energy-generating elements 11 is prepared (FIG. 5A). In this embodiment, a silicon substrate is used as the substrate, but the present invention is not limited to a silicon substrate, and a glass substrate, a plastic substrate, or the like can also be used. The energy-generating elements 11 are not specifically limited insofar as ejection energy for ejecting liquid is given to the liquid and the liquid can be ejected from the ejection orifices 7. For example, when a heat-generating resistance element is used as the energy-generating element 11, the heat-generating resistance element heats liquid in proximity thereto, thereby causing the liquid to change its state to generate ejection energy. Note that, to each energy-generating element 11, a control signal input electrode (not shown) for operating the energy-generating element 11 is connected. Further, the silicon substrate 10 may be additionally provided with various kinds of functional layers such as a protective layer (not shown) for the purpose of improving the durability of the energy-generating elements 11 and an adhesiveness improving layer (not shown) for the purpose of improving the adhesiveness between a positive resist material to be described later and the silicon substrate 10.

Step (b)

The positive resist material is applied onto the silicon substrate 10 and patterning is carried out through a series of photolithography steps to form a bubbling chamber and ink flow path pattern 15 (FIG. 5B). The bubbling chamber and ink flow path pattern 15 is required to be dissolved and removed in a subsequent step, and thus, a positive resist material is used for the bubbling chamber and ink flow path pattern 15. It is preferred that, as the positive resist material, a vinyl-ketone-based photo-degration type polymer compound such as polymethyl isopropenyl ketone or polyvinyl ketone, or an acrylic-based photo-degration type polymer compound be used. One kind of those materials may be used alone, or two or more kinds of them may be used in combination. When applying the positive resist material, a general-purpose applying process such as spin coating or slit coating may be used.

Step (c)

Next, a cationically polymerizable epoxy resin composition is applied onto the silicon substrate 10 having the bubbling chamber and ink flow path pattern 15 formed thereon to form the ink flow path forming layer 13 as a resin composition layer containing the cationically polymerizable epoxy resin composition (FIG. 5C). As necessary, an additional surface modifying treatment such as a hydrophobic treatment or hydrophilic treatment (not shown) may be carried out on the ink flow path forming layer 13.

In the present invention, the cationically polymerizable epoxy resin composition at least contains (A) a multifunctional epoxy resin, (B) a compound which generates an acid by light irradiation, and (C) a compound represented by the above-mentioned structural formula (1) and/or structural formula (2).

<(A) Multifunctional Epoxy Resin>

As the multifunctional epoxy resin as a base of the cationically polymerizable epoxy resin composition, it is preferred to use the following multifunctional epoxy resins from the viewpoint of mechanical strength as a structural material, resistance to ink when used as an ink jet recording head, resolution, and the like. As the multifunctional epoxy resin, it is preferred to use a bisphenol A type multifunctional epoxy resin, a novolac type multifunctional epoxy resin, a multifunctional epoxy resin having an oxycyclohexane skeleton, or the like. One kind of those materials may be used alone, or two or more kinds of them may be used in combination.

The epoxy equivalent of the multifunctional epoxy resin is preferably 2,000 or less, and more preferably 1,000 or less. When the epoxy equivalent is 2,000 or less, the crosslinking density is not reduced in the curing reaction, and sufficient adhesiveness and sufficient resistance to ink are obtained. Note that, the epoxy equivalent is a value measured by neutralization titration based on JIS K-7236.

The weight average molecular weight of the multifunctional epoxy resin is preferably 500 or more and 100,000 or less, and more preferably 1,000 or more and 50,000 or less. Note that, the weight average molecular weight is a value measured by GPC in terms of polystyrene.

In particular, it is preferred that the multifunctional epoxy resin be at least one of compounds represented by the following structural formulae (3) to (7):

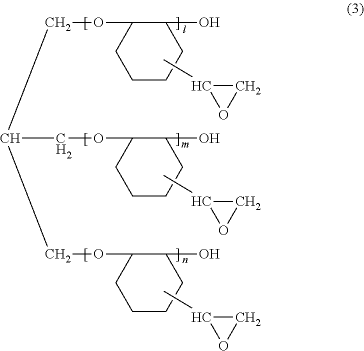

in the structural formula (3), l, m, and n are positive integers;

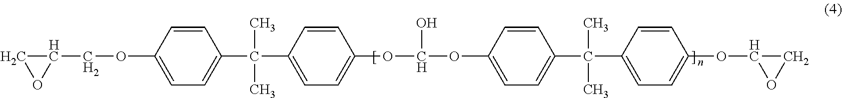

in the structural formula (4), n is a positive integer;

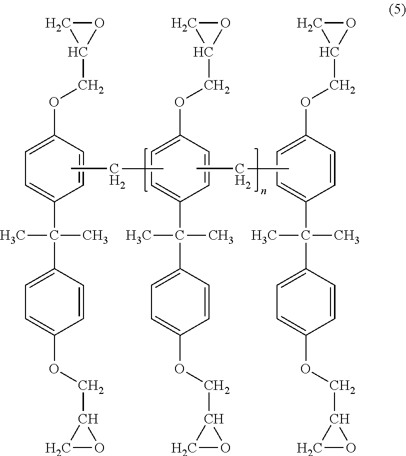

in the structural formula (5), n is a positive integer;

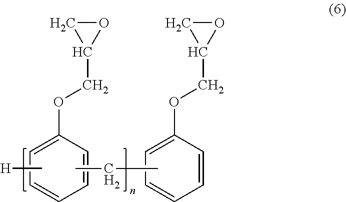

in the structural formula (6), n is a positive integer;

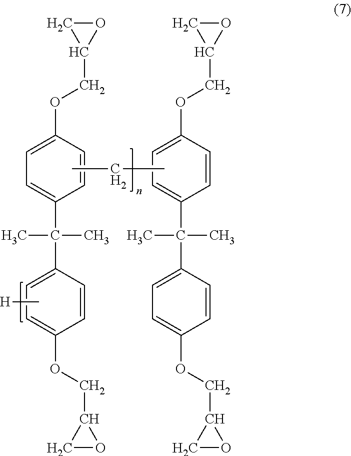

in the structural formula (7), n is a positive integer.

It is preferred that, in the above-mentioned structural formula (3), each of l, m, and n be 1 or more and 200 or less. It is preferred that, in the above-mentioned structural formula (4), n be 1 or more and 400 or less. It is preferred that, in the above-mentioned structural formula (5), n be 1 or more and 200 or less. It is preferred that, in the above-mentioned structural formula (6), n be 1 or more and 600 or less. It is preferred that, in the above-mentioned structural formula (7), n be 1 or more and 300 or less.

<(B) Compound which Generates Acid by Light Irradiation>

In the process according to the present invention, in order to cure the above-mentioned multifunctional epoxy resin (A), a compound which generates an acid by light irradiation (photoacid generator) is used. The photoacid generator is not specifically limited, and, for example, an aromatic sulfonium salt or an aromatic iodonium salt may be used. Specifically, SP-150, SP-170, or SP-172 (trade names, manufactured by ADEKA CORPORATION), DTS-103 or NDS-103 (trade names, manufactured by Midori Kagaku Co., Ltd.), or the like may be used. One kind of those materials may be used alone, or two or more kinds of them may be used in combination. Further, for the purpose of wavelength sensitization, a sensitizer such as SP-100 (trade name, manufactured by ADEKA CORPORATION) may be additionally used.

The mixed amount of the compound (B) which generates an acid by light irradiation is preferably 0.1 parts by mass or more and 20 parts by mass or less, more preferably 1 part by mass or more and 15 parts by mass or less, and further preferably 2 parts by mass or more and 10 parts by mass or less with respect to 100 parts by mass of the multifunctional epoxy resin (A).

<(C) Compound Represented by Above-Mentioned Structural Formula (1) and/or Structural Formula (2)>

In the process according to the present invention, in addition to the above-mentioned constituents, a volatile reactant is used which volatilizes in PEB to be described later in a portion that is not irradiated with light and which can form a cross-linked structure with the multifunctional epoxy resin in a portion that is irradiated with light. Specifically, the compound represented by the above-mentioned structural formula (1) and/or structural formula (2) (hereinafter referred to as the compound (C)) is used. The compound (C) volatilizes (sublimes) at a relatively low temperature, and forms a cross-linked structure with the multifunctional epoxy resin in the presence of an acid. Therefore, in PEB, by transportation of a monomer component containing the compound (C) from the unexposed portion to the exposed portion, the volume is reduced, and in addition, by volatilization (sublimation) of the compound (C) selectively occurring in the unexposed portion, the volume is reduced as well. This effect enables formation of the deep concavity 4 in an uncured portion 18 illustrated in FIG. 5E to be described later.

The mixed amount of the compound (C) can be appropriately adjusted in accordance with the depth d of the concavity 4 to be formed. However, the mixed amount of the compound (C) is preferably 1 part by mass or more and 80 parts by mass or less, more preferably 3 parts by mass or more and 60 parts by mass or less, and further preferably 5 parts by mass or more and 40 parts by mass or less with respect to 100 parts by mass of the multifunctional epoxy resin (A). When the mixed amount is 1 part by mass or more, a sufficiently deep concavity 4 can be formed. Further, when the mixed amount is 80 parts by mass or less, the cross-link density between epoxy groups becomes higher, and thus sufficiently adhesiveness can be obtained. Note that, as the mixed amount of the compound (C) increases, the depth d of the concavity 4 can be more increased, and the taper angle θ can be more reduced.

Each of the compound represented by the above-mentioned structural formula (1) and the compound represented by the above-mentioned structural formula (2) may be used alone, or the both may be used in combination. When the compound represented by the above-mentioned structural formula (1) and the compound represented by the above-mentioned structural formula (2) are used in combination, the mixed amounts thereof are not specifically limited. For example, the ratio of the compound represented by the above-mentioned structural formula (1) to the sum of the compound represented by the above-mentioned structural formula (1) and the compound represented by the above-mentioned structural formula (2) (mass ratio) can be 10 mass % or more and 90 mass % or less.

Note that, the compound represented by the above-mentioned structural formula (1) and the compound represented by the above-mentioned structural formula (2) are available from Central Glass Co., Ltd. under the trade names of 1,4-HFAB and 1,3-HFAB, respectively.

<Other Additives>

The cationically polymerizable epoxy resin composition according to the present invention can contain various additives other than the above-mentioned (A) to (C) as necessary. For example, a flexibility imparting agent added for the purpose of reducing the elastic modulus of the cured epoxy resin or a silane coupling agent added for the purpose of obtaining further adhesiveness with the base may be contained.

<Application Solvent>

As an application solvent for applying the cationically polymerizable epoxy resin composition according to the present invention, an application solvent which dissolves the above-mentioned constituents but is less liable to dissolve the positive resist material forming the bubbling chamber and ink flow path pattern 15 can be selectively used. Further, when the volatility of the application solvent is low, high temperature treatment is required when the solvent is dried after the application, and thus, the compound (C) may volatilize. Therefore, it is preferred that a solvent which volatilizes at 40 to 90° C. be used. Examples of the application solvent may include an alcohol-based solvent such as ethanol or isopropyl alcohol, a ketone-based solvent such as acetone, methyl isobutyl ketone, diisobutyl ketone, or cyclohexanone, an aromatic-based solvent such as toluene or xylene, ethyl lactate, propylene glycol monomethyl ether, diethylene glycol monomethyl ether, and diethylene glycol dimethyl ether. One kind of those materials may be used alone, or two or more kinds of them may be mixedly used. Note that, the drying of the application solvent may be carried out under a reduced pressure or with the addition of heat under a reduced pressure for the purpose of volatilizing the solvent at a low temperature.

<Drying Temperature of Application Solvent by Heat Treatment>

When the cationically polymerizable epoxy resin composition is applied onto the silicon substrate 10 having the bubbling chamber and ink flow path pattern 15 formed thereon, and the application solvent is dried by heat treatment, it is preferred to dry the solvent at a relatively low temperature to prevent the compound (C) from volatilizing. The temperature of the heat treatment for drying the solvent is lower preferably by 5° C. or more and more preferably by 10° C. or more than the temperature of the first heat treatment (first PEB) to be described later.

Specifically, when the compound represented by the above-mentioned structural formula (1) is used as the compound (C), the temperature of the heat treatment for drying the solvent is preferably 40° C. or higher and 90° C. or lower, and more preferably 50° C. or higher and 80° C. or lower. When the compound represented by the above-mentioned structural formula (2) is used as the compound (C), the temperature of the heat treatment for drying the solvent is preferably 40° C. or higher and 65° C. or lower, and more preferably 45° C. or higher and 60° C. or lower.

The thickness of the ink flow path forming layer 13 to be formed is preferably 5 μm or more and 100 μm or less, and more preferably 8 μm or more and 50 μm or less.

Steps (d) and (e)

Light irradiation is carried out on the ink flow path forming layer 13 via a first photomask 16 to carry out a first pattern exposure (FIG. 5D). After that, a first heat treatment (first PEB) is carried out. With the series of steps, polymerization reaction proceeds in the portion which is irradiated with light to form a cured portion 17, and the concavity 4 is formed on the surface of the portion at which light is blocked by the first photomask 16 (uncured portion 18) (FIG. 5E).

The wavelength of the exposure light in the first pattern exposure is not specifically limited, and, for example, an i-line (wavelength: 365 nm) or KrF excimer laser light (wavelength: 248 nm) can be used. The amount of exposure light in the first pattern exposure can be appropriately selected, and can be, for example, 500 J/m² or more and 10,000 J/m² or less.

The conditions of the first PEB can be appropriately set taking the following points into consideration.

<Patternability>

It is preferred that the temperature of the first PEB be 70° C. or higher and 120° C. or lower. When the temperature of the first PEB is 70° C. or higher, sufficient crosslinking are made in the portion which is irradiated with light to obtain sufficient adhesiveness with the base. When the temperature of the first PEB is 120° C. or lower, an acid generated from a photo polymerization initiator by the light irradiation does not diffuse to the portion which is not irradiated with light, and thus, the resolution can be prevented from being lowered. The length of time of the first PEB is not specifically limited insofar as the length of time for treatment is sufficient for the cross-linking reaction in the exposed portion to proceed. When the first PEB is carried out in the above-mentioned temperature range, it is preferred that the length of time for treatment be one minute or more and 10 minutes or less.

<Flowability and Volatility>

In order to cause a monomer component containing the compound (C) to migrate from the unexposed portion to the exposed portion and to volatilize (sublime) the compound (C) with high efficiency, it is preferred to carry out the first PEB at a temperature which is equal to or higher than the melting point of the compound (C).

When the compound represented by the above-mentioned structural formula (1) (melting point: 88° C.) is used as the compound (C), the first PEB is carried out preferably at 95° C. or higher, and more preferably at 100° C. or higher. Further, from the viewpoint of patternability described above, the first PEB is carried out preferably at 120° C. or lower, and more preferably at 115° C. or lower.

When the compound represented by the above-mentioned structural formula (2) (melting point: 22° C.) is used as the compound (C), from the viewpoint of patternability described above, the first PEB is carried out preferably at 70° C. or higher, and more preferably at 75° C. or higher. Further, from the viewpoint of patternability described above, the first PEB is carried out preferably at 120° C. or lower, and more preferably at 115° C. or lower.

Further, for the purpose of volatilizing the compound (C) at a low temperature with high efficiency in the first PEB, it is preferred that the first PEB be carried out under a reduced pressure. With regard to the extent of reduction in pressure in the first PEB, the reduced pressure is preferably −400 mmHg or less, and more preferably −600 mmHg or less.

The first PEB can be carried out, for example, on a hot plate.

The diameter φa of the concavity 4 to be formed can be, for example, 10 μm or more and 100 μm or less. The depth d of the concavity 4 can be, for example, 4 μm or more and 10 μm or less, and is preferably 4.5 μm or more and 8 μm or less.

Steps (f) and (g)

Then, light irradiation is carried out on the unexposed portion of the ink flow path forming layer 13 via a second photomask 19 to carry out the second pattern exposure (FIG. 5F). After that, the second heat treatment (second PEB) is carried out. Further, the unexposed portion in the first pattern exposure and in the second pattern exposure is removed by development treatment to form the ejection orifice 7 for ejecting ink and the ejection portion 8 having a taper shape in which an inner diameter reduces toward the ejection orifice 7 (FIG. 5G).

The wavelength of the exposure light in the second pattern exposure is not specifically limited, and, for example, an i-line or KrF excimer laser light can be used. The amount of exposure light in the second pattern exposure can be appropriately selected, and can be, for example, 500 J/m² or more and 10,000 J/m² or less.

The conditions of the second PEB can be similar to those of the first PEB.

A developer used in the development treatment is not specifically limited, and, for example, methyl isobutyl ketone or xylene can be used. One kind of those materials may be used alone, or two or more kinds of them may be mixedly used as a mixed solvent. After the development treatment, rinsing treatment with isopropyl alcohol or the like, postbaking, or the like may be carried out as necessary.

The diameter φb of the ejection orifice 7 to be formed can be, for example, 5 μm or more and 80 μm or less. The taper angle θ of the ejection portion 8 can be, for example, 85° or less, and is preferably 80° or less.

Step (h)

Next, the ink supply port 14 passing through the silicon substrate 10 is formed (FIG. 5H). The ink supply port 14 can be formed by sandblasting, dry etching, wet etching, or the like, or a combination thereof.

As an example, description is made of anisotropic etching using an aqueous solution of potassium hydroxide, sodium hydroxide, tetramethylammonium hydroxide, or the like as an alkaline etchant. By carrying out alkaline chemical etching, a silicon substrate having a crystal orientation of <100> or <110> can have selectivity between a depth direction and a width direction with respect to the direction of progress of the etching, thereby capable of obtaining anisotropy of the etching. In particular, in a silicon substrate having the crystal orientation of <100>, the etching width geometrically determines the etching depth, and thus, the etching depth can be controlled. For example, a hole which is tapered from an etching start surface in the depth direction with a taper angle of 54.7° can be formed. By carrying out the anisotropic etching under a state in which an appropriate resin material or inorganic film resistant to the etchant is used as the mask, the ink supply port 14 passing through the silicon substrate 10 can be formed.

Step (i)

Next, by removing the bubbling chamber and ink flow path pattern 15, a bubbling chamber and ink flow path 20 communicating with the ejection portion 8 is formed (FIG. 5I). With regard to the process of removing the bubbling chamber and ink flow path pattern 15, it is preferred to apply light including light of the photosensitive wavelength of the positive resist material used in Step (b) from a surface in which the ejection orifice 7 is formed to cause the positive resist material to be soluble and then to dissolve and remove the positive resist material using an appropriate solvent.

Next, after a cutting and separating step (not shown), heat treatment is carried out as necessary to completely cure the cationically polymerizable epoxy resin composition. Further, bonding of a member for supplying ink (not shown), electrical connection for driving the energy-generating elements 11 (not shown), and the like are carried out to complete the ink jet recording head.

### Second Embodiment

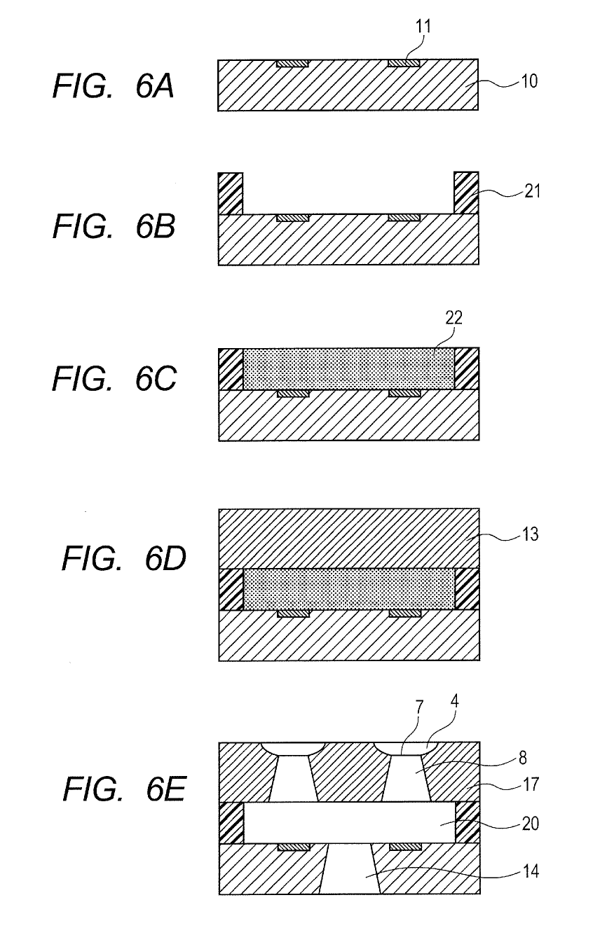

A second embodiment of the present invention is described in the following with reference to FIGS. 6A to 6E. Note that, steps illustrated in FIGS. 6A to 6E are hereinafter referred to as Steps (a) to (e), respectively.

Step (a)

First, similarly to the case of the first embodiment, a silicon substrate 10 including energy-generating elements 11 is prepared (FIG. 6A).

Step (b)

A Wall 21 of the bubbling chamber and ink flow path pattern is formed on the silicon substrate (FIG. 6B). The wall 21 of the bubbling chamber and ink flow path pattern can be formed by an ordinary photolithography process using a negative photoresist. As the negative photoresist, the cationically polymerizable epoxy resin composition in the first embodiment may be used.

Step (c)

Next, a resin composition 22 which can be dissolved and removed is filled in a portion surrounded by the walls 21 of the bubbling chamber and ink flow path pattern (FIG. 6C). As the process of filling the resin composition 22 which can be dissolved and removed, for example, there may be used a process in which the positive resist material in the first embodiment is applied onto the silicon substrate 10 having the walls 21 of the bubbling chamber and ink flow path pattern formed thereon, the positive resist material is dried, and then the positive resist material is flattened by a known method such as polishing.

Steps (d) and (e)

Next, similarly to the case of the first embodiment, the cationically polymerizable epoxy resin composition in the first embodiment is applied onto the wall 21 of the bubbling chamber and ink flow path pattern and the resin composition 22 which can be dissolved and removed to form an ink flow path forming layer 13 (FIG. 6D). The subsequent steps are carried out similarly to those of the first embodiment, and an ejection orifice 7, an ejection portion 8, an ink supply port 14, and a bubbling chamber and ink flow path 20 are formed (FIG. 6E). In this way, the ink jet recording head is completed.

### Third Embodiment

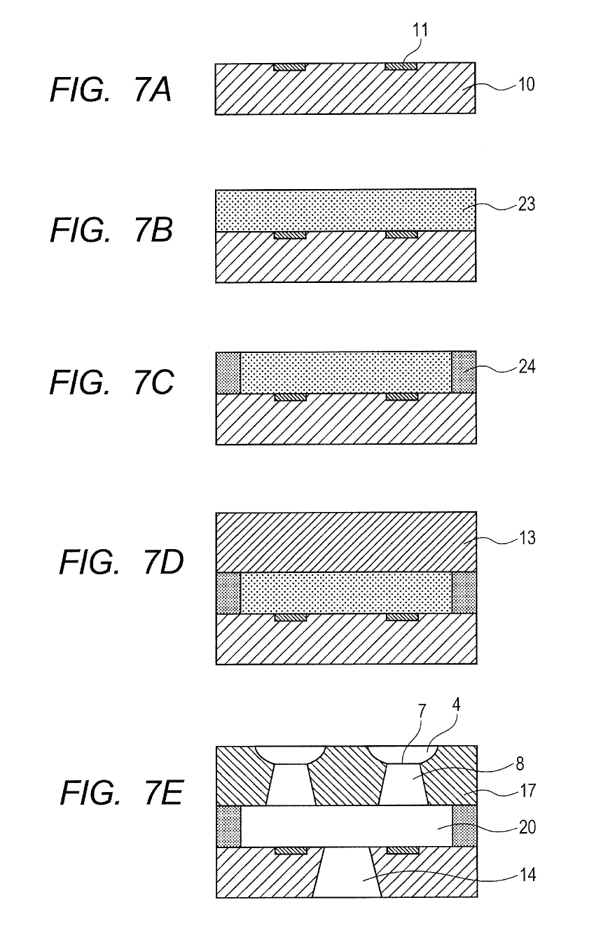

A third embodiment of the present invention is described in the following with reference to FIGS. 7A to 7E. Note that, steps illustrated in FIGS. 7A to 7E are hereinafter referred to as Steps (a) to (e), respectively.

Step (a)

First, similarly to the case of the first embodiment, a silicon substrate 10 including energy-generating elements 11 is prepared (FIG. 7A).

Steps (b) and (c)

A negative photoresist 23 is applied onto the silicon substrate 10 (FIG. 7B) and pattern exposure is carried out to form a latent image 24 of the bubbling chamber and ink flow path pattern (FIG. 7C). As the negative photoresist, the cationically polymerizable epoxy resin composition in the first embodiment may be used.

Steps (d) and (e)

Next, similarly to the case of the first embodiment, the cationically polymerizable epoxy resin composition in the first embodiment is applied onto the negative photoresist 23 and the latent image 24 of the bubbling chamber and ink flow path pattern to form an ink flow path forming layer 13 (FIG. 7D). The subsequent steps are carried out similarly to those of the first embodiment, and an ejection orifice 7, an ejection portion 8, an ink supply port 14, and a bubbling chamber and ink flow path 20 are formed (FIG. 7E). In this way, the ink jet recording head is completed.

Note that, in the third embodiment, when the first and second pattern exposures are carried out on the ink flow path forming layer 13, it is preferred that the negative photoresist 23 thereunder be not exposed to light. For example, the following processes may be used.

<Process of Separating Photosensitive Wavelength>

As the negative photoresist 23 which is the lower layer, a material which is sensitive only to a Deep-UV region (wavelength region of 300 nm or less) is used, and light irradiation is carried out using a Deep-UV exposure apparatus (for example, a KrF stepper). Further, as the ink flow path forming layer 13 which is the upper layer, a material which is sensitive to an i-line is used, and light irradiation is carried out using an i-line exposure apparatus (for example, an i-line stepper). This can prevent the lower layer from being exposed when the light irradiation is carried out on the upper layer.

<Process of Differentiating Sensitivity>

The photosensitive wavelength of the negative photoresist 23 which is the lower layer and the photosensitive wavelength of the ink flow path forming layer 13 which is the upper layer may be the same, but the sensitivity of the upper layer is five times or more as high as that of the lower layer. This can reduce exposure of the lower layer when the light irradiation is carried out on the upper layer.

### EXAMPLES

The present invention is hereinafter described in detail with reference to examples below. However, the present invention is not limited by the examples.

### Example 1

An ink jet recording head was manufactured in accordance with the steps illustrated in FIGS. 5A to 5I. First, the silicon substrate 10 illustrated in FIG. 5A was prepared. In this example, the silicon substrate 10 was prepared in which electrothermal conversion elements (heaters formed of HfB₂) as the energy-generating elements 11 were formed on a silicon substrate of 8 inches. Further, the silicon substrate included a lamination film (not shown) of SiN+Ta at portions where the ink flow path and nozzles were to be formed.

As the positive resist, polymethyl isopropenyl ketone (trade name: ODUR, manufactured by TOKYO OHKA KOGYO CO., LTD.) was spin coated on the silicon substrate 10, and baking was carried out at 120° C. for 3 minutes. The thickness of the resist layer after the baking was 15 μm. Then, pattern exposure was carried out using a Deep-UV exposure apparatus (trade name: UX-3200, manufactured by USHIO INC.) with the amount of exposure light being 23,000 mJ/cm². After that, development was carried out with methyl isobutyl ketone and rinsing treatment was carried out with isopropyl alcohol to form the bubbling chamber and ink flow path pattern 15 having a thickness of 15 μm (FIG. 5B).

Then, a cationically polymerizable epoxy resin composition of the following composition was spin coated on the bubbling chamber and ink flow path pattern 15 so as to have a thickness of 13 μm, and drying of the solvent (prebaking) was carried out on a hot plate at 70° C. for 3 minutes. In this way, the ink flow path forming layer 13 was formed (FIG. 5C). The thickness of the ink flow path forming layer 13 on the bubbling chamber and ink flow path pattern 15 was 13 μm.
Multifunctional epoxy resin: the compound represented by the above-mentioned structural formula (3) (mixture where l, m, and n are 1 to 10) (trade name: EHPE, manufactured by Daicel Corporation) . . . 100 parts by mass
Photopolimerization initiator: SP-172 (trade name, manufactured by ADEKA CORPORATION) . . . 5 parts by mass
Volatile reactant: the compound represented by the above-mentioned structural formula (1) (trade name: 1,4-HFAB, manufactured by Central Glass Co., Ltd.) . . . 20 parts by mass
Application solvent: xylene . . . 100 parts by mass

Next, light irradiation was carried out using an i-line stepper (trade name: i5, manufactured by Canon Inc.) via the first photomask 16 with the amount of exposure light being 2,500 J/m² (FIG. 5D). After that, the first PEB was carried out on a hot plate at 100° C. for 3 minutes to form the concavity 4 (FIG. 5E). Note that, as the concavity 4, a concavity having the diameter φa of 25 μm was formed. The depth d of the concavity 4 at that time was measured under a laser microscope (manufactured by KEYENCE CORPORATION).

Then, light irradiation was carried out using the i-line stepper (trade name: i5, manufactured by Canon Inc.) via the second photomask 19 with the amount of exposure light being 3,500 J/m² (FIG. 5F). After that, the second PEB was carried out on a hot plate at 100° C. for 3 minutes. Further, development was carried out with a mixed solvent in which methyl isobutyl ketone:xylene=1:1 (mass ratio), and rinsing treatment was carried out with isopropyl alcohol to form the ejection orifice 7 and the ejection portion 8 (FIG. 5G). Note that, in this example, as the ejection orifice 7, an ejection orifice having a diameter φb of 15 μm was formed.

Then, an etching mask (not shown) with an opening having a width of 1 mm and a length of 24 mm formed therein was formed on a rear surface of the silicon substrate 10 using a polyether amide resin composition (trade name: HIMAL, manufactured by Hitachi Chemical Company, Ltd.). The silicon substrate 10 was soaked in an aqueous solution of 22 mass % tetramethylammonium hydroxide held at 80° C., and anisotropic etching of the silicon substrate 10 was carried out to form the ink supply port 14 (FIG. 5H). Note that, in this case, for the purpose of protecting the resin layer on the surface of the silicon substrate 10 against the etchant, a protective film (not shown, trade name: OBC, manufactured by TOKYO OHKA KOGYO CO., LTD.) was applied in advance on the surface of the silicon substrate 10, and then, the anisotropic etching was carried out.

Then, the protective film was dissolved and removed using xylene, and after that, the entire surface was exposed to light using a Deep-UV exposure apparatus (trade name: UX-3200, manufactured by USHIO INC.) with the amount of exposure light being 20,000 mJ/cm². After that, the silicon substrate 10 was soaked in methyl lactate with ultrasonic waves applied thereto to dissolve and remove the bubbling chamber and ink flow path pattern 15, thereby forming the bubbling chamber and ink flow path 20 communicating to the ink supply port 14 (FIG. 5I).

Then, heat treatment was carried out at 200° C. for 60 minutes to completely cure the ink flow path forming layer 13. After that, the cutting and separating step (not shown), bonding of a member for supplying ink (not shown), electrical connection for driving the energy-generating elements 11 (not shown), and the like are carried out to complete the ink jet recording head.

The ink jet recording head manufactured in this way was cut so that a section of the ejection orifice 7 and the ejection portion 8 could be observed, and observation was made with a scanning electron microscope (trade name: JSM-7500F, manufactured by JEOL Ltd.) to measure the taper angle θ. Table 1 shows the taper angle θ, the diameter φa of the concavity 4, the depth d of the concavity 4, and the diameter φb of the ejection orifice.

### Examples 2 to 5

An ink jet recording head was manufactured similarly to the case of Example 1 except that the mixed amount of 1,4-HFAB was changed as shown in Table 1, and the taper angle θ and the like were measured. The results are shown in Table 1.

### Example 6

Instead of 1,4-HFAB, the compound represented by the above-mentioned structural formula (2) (trade name: 1,3-HFAB, manufactured by Central Glass Co., Ltd.) was mixed. Further, the prebaking after the cationically polymerizable epoxy resin composition was spin coated was carried out at 60° C. for 3 minutes. Except for that, similarly to the case of Example 1, an ink jet recording head was manufactured, and the taper angle θ and the like were measured. The results are shown in Table 1.

### Example 7

Instead of mixing 20 parts by mass of 1,4-HFAB, 10 parts by mass of 1,4-HFAB and 10 parts by mass of 1,3-HFAB were mixed. Except for that, similarly to the case of Example 1, an ink jet recording head was manufactured, and the taper angle θ and the like were measured. The results are shown in Table 1.

### Example 8

An ink jet recording head was manufactured similarly to the case of Example 1 except that the first PEB was carried out under a reduced pressure of −600 mmHg, and the taper angle θ and the like were measured. The results are shown in Table 1.

### Example 9

The prebaking after the cationically polymerizable epoxy resin composition was spin coated was carried out on a hot plate at 50° C. for 3 minutes. Except for that, similarly to the case of Example 6, an ink jet recording head was manufactured, and the taper angle θ and the like were measured. The results are shown in Table 1.

### Example 10

Instead of EHPE which is the compound represented by the above-mentioned structural formula (3), the compound represented by the above-mentioned structural formula (4) (mixture where n=2 to 7) was mixed. Except for that, similarly to the case of Example 1, an ink jet recording head was manufactured, and the taper angle θ and the like were measured. The results are shown in Table 2.

### Example 11

Instead of EHPE which is the compound represented by the above-mentioned structural formula (3), the compound represented by the above-mentioned structural formula (5) (mixture where n=3 to 5) was mixed. Except for that, similarly to the case of Example 1, an ink jet recording head was manufactured, and the taper angle θ and the like were measured. The results are shown in Table 2.

### Example 12

Instead of EHPE which is the compound represented by the above-mentioned structural formula (3), the compound represented by the above-mentioned structural formula (6) (mixture where n=2 to 20) was mixed. Except for that, similarly to the case of Example 1, an ink jet recording head was manufactured, and the taper angle θ and the like were measured. The results are shown in Table 2.

### Example 13

Instead of EHPE which is the compound represented by the above-mentioned structural formula (3), the compound represented by the above-mentioned structural formula (7) (mixture where n=5 to 20) was mixed. Except for that, similarly to the case of Example 1, an ink jet recording head was manufactured, and the taper angle θ and the like were measured. The results are shown in Table 2.

### Example 14

An ink jet recording head was manufactured in accordance with the steps illustrated in FIGS. 6A to 6E,. First, the silicon substrate 10 which was the same as that in Example 1 was prepared (FIG. 6A).

A negative resist of the following composition was spin coated on the silicon substrate 10 so as to have a thickness of 15 μm, and prebaking was carried out on a hot plate at 90° C. for 3 minutes. Then, light irradiation was carried out using an i-line stepper (trade name: i5, manufactured by Canon Inc.) via a photomask (not shown) with the amount of exposure light being 4,000 J/m². After that, PEB was carried out on a hot plate at 90° C. for 3 minutes. Development was carried out with methyl isobutyl ketone, and rinsing treatment was carried out with isopropyl alcohol to form the wall 21 of the bubbling chamber and ink flow path pattern (FIG. 6B).
Multifunctional epoxy resin: the compound represented by the above-mentioned structural formula (3) (mixture wherein l, m, and n are 1 to 10) (trade name: EHPE, manufactured by Daicel Corporation) . . . 100 parts by mass
Photopolimerization initiator: SP-172 (trade name, manufactured by ADEKA CORPORATION) . . . 5 parts by mass
Application solvent: methyl isobutyl ketone . . . 100 parts by mass

Next, polymethyl isopropenyl ketone (trade name: ODUR, manufactured by TOKYO OHKA KOGYO CO., LTD.) was spin coated, and baking was carried out at 100° C. for 3 minutes. After that, flattening was carried out by chemical-mechanical polishing, and the resin composition 22 which can be dissolved and removed was filled in space inside the wall 21 of the bubbling chamber and ink flow path pattern (FIG. 6C). Then, the cationically polymerizable epoxy resin composition which was the same as that in Example 1 was used to form the ink flow path forming layer 13 similarly to the case of Example 1 (FIG. 6D). After that, similarly to the case of Example 1, an ink jet recording head was completed (FIG. 6E). Further, similarly to the case of Example 1, the taper angle θ and the like were measured. The results are shown in Table 3.

### Example 15

An ink jet recording head was manufactured in accordance with the steps illustrated in FIGS. 7A to 7E. First, the silicon substrate 10 which was the same as that in Example 1 was prepared (FIG. 7A).

The negative photoresist 23 of the following composition was spin coated on the silicon substrate 10 so as to have a thickness of 15 μm, and prebaking was carried out on a hot plate at 90° C. for 3 minutes (FIG. 7B). Then, light irradiation was carried out using a KrF-line stepper (trade name: GMR, manufactured by Canon Inc.) via a photomask (not shown) with the amount of exposure light being 2,000 J/m². After that, PEB was carried out on a hot plate at 90° C. for 3 minutes to form the latent image 24 of the bubbling chamber and ink flow path pattern (FIG. 7C).
Multifunctional epoxy resin: the compound represented by the above-mentioned structural formula (3) (mixture where l, m, and n are 1 to 10) (trade name: EHPE, manufactured by Daicel Corporation) . . . 100 parts by mass
Photopolimerization initiator: SP-170 (trade name, manufactured by ADEKA CORPORATION) . . . 6 parts by mass
Application solvent: methyl isobutyl ketone . . . 100 parts by mass

Next, the cationically polymerizable epoxy resin composition which was the same as that in Example 1 was used to form the ink flow path forming layer 13 similarly to the case of Example 1 (FIG. 7D). After that, simultaneously with development of the cationically polymerizable epoxy resin composition, development of the negative photoresist 23 was carried out to dissolve and remove the unexposed portion. Except for that, similarly to the case of Example 1, an ink jet recording head was completed (FIG. 7E). Further, similarly to the case of Example 1, the taper angle θ and the like were measured. The results are shown in Table 3.

### Comparative Example 1

An ink jet recording head was manufactured similarly to the case of Example 1 except that a cationically polymerizable epoxy resin composition which does not contain 1,4-HFAB was used, and the taper angle θ and the like were measured. The results are shown in Table 1.

### Comparative Example 2

An ink jet recording head was manufactured similarly to the case of Example 10 except that a cationically polymerizable epoxy resin composition which does not contain 1,4-HFAB was used, and the taper angle θ and the like were measured. The results are shown in Table 2.

### Comparative Example 3

An ink jet recording head was manufactured similarly to the case of Example 11 except that a cationically polymerizable epoxy resin composition which does not contain 1,4-HFAB was used, and the taper angle θ and the like were measured. The results are shown in Table 2.

### Comparative Example 4

An ink jet recording head was manufactured similarly to the case of Example 12 except that a cationically polymerizable epoxy resin composition which does not contain 1,4-HFAB was used, and the taper angle θ and the like were measured. The results are shown in Table 2.

### Comparative Example 5

An ink jet recording head was manufactured similarly to the case of Example 13 except that a cationically polymerizable epoxy resin composition which does not contain 1,4-HFAB was used, and the taper angle θ and the like were measured. The results are shown in Table 2.

### Comparative Example 6

Instead of 1,4-HFAB, a compound represented by the following structural formula (8) (trade name: BIS-AF, manufactured by Central Glass Co., Ltd., melting point: 162° C.) was mixed. Except for that, similarly to the case of Example 1, an ink jet recording head was manufactured, and the taper angle θ and the like were measured. The results are shown in Table 4.

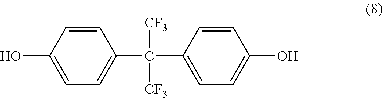 [SMILES: Oc1ccc(C(c2ccc(O)cc2)(C(F)(F)F)C(F)(F)F)cc1]

### Comparative Example 7

Instead of 1,4-HFAB, a compound represented by the following structural formula (9) (trade name: HFAB, manufactured by Central Glass Co., Ltd.) was mixed. Except for that, similarly to the case of Example 1, an attempt was made to manufacture an ink jet recording head. However, in developing the cationically polymerizable epoxy resin composition, peeling was partly caused, and thus, the ink jet recording head could not be manufactured.

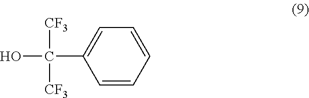 [SMILES: OC(c1ccccc1)(C(F)(F)F)C(F)(F)F]

TABLE 1

| | (A) | | (B) | | (C) | | | | | | |
|---|---|---|---|---|---|---|---|---|---|---|---|
| | | Mixed | | Mixed | | Mixed | | | | | |
| | | Amount | | Amount | | Amount | | | | | |
| | | (part by | | (part by | | (part by | φa | φb | d | θ | |
| | Kind | mass) | Kind | mass) | Kind | mass) | (μm) | (μm) | (μm) | (°) | Remarks |
| Example 1 | Structural | 100 | SP-172 | 5 | Structural | 20 | 25 | 15 | 5.6 | 78 | |
| | formula (3) | | | | formula (1) | | | | | | |
| Example 2 | Structural | 100 | SP-172 | 5 | Structural | 5 | 25 | 15 | 4.8 | 80 | |
| | formula (3) | | | | formula (1) | | | | | | |
| Example 3 | Structural | 100 | SP-172 | 5 | Structural | 10 | 25 | 15 | 5.2 | 79 | |
| | formula (3) | | | | formula (1) | | | | | | |
| Example 4 | Structural | 100 | SP-172 | 5 | Structural | 30 | 25 | 15 | 6.0 | 77 | |
| | formula (3) | | | | formula (1) | | | | | | |
| Example 5 | Structural | 100 | SP-172 | 5 | Structural | 40 | 25 | 15 | 6.4 | 76 | |
| | formula (3) | | | | formula (1) | | | | | | |
| Example 6 | Structural | 100 | SP-172 | 5 | Structural | 20 | 25 | 15 | 6.3 | 76 | Prebaking (at |
| | formula (3) | | | | formula (2) | | | | | | 60° C. for 3 |
| | | | | | | | | | | | minutes) |
| Example 7 | Structural | 100 | SP-172 | 5 | Structural | 10 | 25 | 15 | 6.2 | 77 | |
| | formula (3) | | | | formula (1) | | | | | | |
| | | | | | Structural | 10 | | | | | |
| | | | | | formula (2) | | | | | | |
| Example 8 | Structural | 100 | SP-172 | 5 | Structural | 20 | 25 | 15 | 6.0 | 77 | First PEB (−600 mmHg) |
| | formula (3) | | | | formula (1) | | | | | | |
| Example 9 | Structural | 100 | SP-172 | 5 | Structural | 20 | 25 | 15 | 6.5 | 75 | Prebaking (at |
| | formula (3) | | | | formula (2) | | | | | | 50° C. for 3 |
| | | | | | | | | | | | minutes) |
| Comparative | Structural | 100 | SP-172 | 5 | — | — | 25 | 15 | 4.0 | 82 | |
| Example 1 | formula (3) | | | | | | | | | | |

TABLE 2

| | (A) | | (B) | | (C) | | | | | | |
|---|---|---|---|---|---|---|---|---|---|---|---|
| | | Mixed | | Mixed | | Mixed | | | | | |
| | | Amount | | Amount | | Amount | | | | | |
| | | (part by | | (part by | | (part by | φa | φb | d | θ | |
| | Kind | mass) | Kind | mass) | Kind | mass) | (μm) | (μm) | (μm) | (°) | Remarks |
| Example 10 | Structural | 100 | SP-172 | 5 | Structural | 20 | 25 | 15 | 5.6 | 78 | |
| | formula (4) | | | | formula (1) | | | | | | |
| Example 11 | Structural | 100 | SP-172 | 5 | Structural | 20 | 25 | 15 | 5.7 | 78 | |
| | formula (5) | | | | formula (1) | | | | | | |
| Example 12 | Structural | 100 | SP-172 | 5 | Structural | 20 | 25 | 15 | 5.7 | 78 | |
| | formula (6) | | | | formula (1) | | | | | | |
| Example 13 | Structural | 100 | SP-172 | 5 | Structural | 20 | 25 | 15 | 5.6 | 78 | |
| | formula (7) | | | | formula (1) | | | | | | |
| Comparative | Structural | 100 | SP-172 | 5 | — | — | 25 | 15 | 4.0 | 82 | |
| Example 2 | formula (4) | | | | | | | | | | |
| Comparative | Structural | 100 | SP-172 | 5 | — | — | 25 | 15 | 4.0 | 83 | |
| Example 3 | formula (5) | | | | | | | | | | |
| Comparative | Structural | 100 | SP-172 | 5 | — | — | 25 | 15 | 4.0 | 82 | |
| Example 4 | formula (6) | | | | | | | | | | |
| Comparative | Structural | 100 | SP-172 | 5 | — | — | 25 | 15 | 4.0 | 82 | |
| Example 5 | formula (7) | | | | | | | | | | |

TABLE 3

| | (A) | | (B) | | (C) | | | | | | |
|---|---|---|---|---|---|---|---|---|---|---|---|
| | | Mixed | | Mixed | | Mixed | | | | | |
| | | Amount | | Amount | | Amount | | | | | |
| | | (part by | | (part by | | (part by | φa | φb | d | θ | |
| | Kind | mass) | Kind | mass) | Kind | mass) | (μm) | (μm) | (μm) | (°) | Remarks |
| Example 14 | Structural | 100 | SP-172 | 5 | Structural | 20 | 25 | 15 | 5.6 | 78 | Production |
| | formula (3) | | | | formula (1) | | | | | | Process of |
| | | | | | | | | | | | FIGS. 6A to 6E |
| Example 15 | Structural | 100 | SP-172 | 5 | Structural | 20 | 25 | 15 | 5.6 | 78 | Production |
| | formula (3) | | | | formula (1) | | | | | | Process of |
| | | | | | | | | | | | FIGS. 7A to 7E |

TABLE 4

| | (A) | | (B) | | (C) | | | | | | |
|---|---|---|---|---|---|---|---|---|---|---|---|
| | | Mixed | | Mixed | | Mixed | | | | | |
| | | Amount | | Amount | | Amount | | | | | |
| | | (part by | | (part by | | (part by | φa | φb | d | θ | |
| | Kind | mass) | Kind | mass) | Kind | mass) | (μm) | (μm) | (μm) | (°) | Remarks |
| Comparative | Structural | 100 | SP-172 | 5 | Structural | 20 | 25 | 15 | 4.0 | 82 | |
| Example 6 | formula (3) | | | | formula (8) | | | | | | |
| Comparative | Structural | 100 | SP-172 | 5 | Structural | 20 | — | — | — | — | The ink jet |
| Example 7 | formula (3) | | | | formula (9) | | | | | | recording |
| | | | | | | | | | | | head could |
| | | | | | | | | | | | not be |
| | | | | | | | | | | | manufactured. |

According to the present invention, an ink jet recording head including an ejection portion having a taper shape with small taper angle can be provided.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2012-055843, filed Mar. 3, 2012 which is hereby incorporated by reference herein in its entirety.

What is claimed is:

1. A process for producing an ink jet recording head, comprising:
forming, on a substrate, a resin composition layer including a cationically polymerizable epoxy resin composition;
carrying out a first pattern exposure and a first heat treatment at the resin composition layer;
carrying out a second pattern exposure and a second heat treatment at an unexposed portion of the resin composition layer; and
removing an unexposed portion in the first pattern exposure and in the second pattern exposure by a development treatment; and
forming an ejection orifice for ejecting ink and an ejection portion having a taper shape in which inner diameter reduces toward the ejection orifice,
wherein the cationically polymerizable epoxy resin composition includes at least:
(A) a multifunctional epoxy resin;
(B) a compound which generates an acid by light irradiation; and
(C) a compound represented by at least one of the following structural formula (1) and the following structural formula (2).

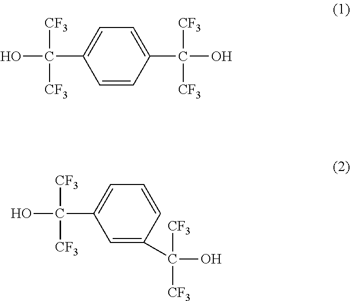 [SMILES: OC(c1ccc(C(O)(C(F)(F)F)C(F)(F)F)cc1)(C(F)(F)F)C(F)(F)F ; OC(c1cccc(C(O)(C(F)(F)F)C(F)(F)F)c1)(C(F)(F)F)C(F)(F)F]

2. A process for producing an ink jet recording head according to claim 1, wherein:
the compound (C) is the compound represented by the structural formula (1); and
the first heat treatment is carried out at 95° C. or higher and at 120° C. or lower.

3. A process for producing an ink jet recording head according to claim 1, wherein:
the compound (C) is the compound represented by the structural formula (2); and
the first heat treatment is carried out at 70° C. or higher and at 120° C. or lower.

4. A process for producing an ink jet recording head according to claim 1, wherein the forming of the resin composition layer on the substrate comprises carrying out a heat treatment at a temperature lower by 5° C. or more than a temperature of the first heat treatment.

5. A process for producing an ink jet recording head according to claim 2, wherein the forming of the resin composition layer on the substrate comprises carrying out a heat treatment at a temperature of 40° C. or higher and 90° C. or lower.

6. A process for producing an ink jet recording head according to claim 3, wherein the forming of the resin composition layer on the substrate comprises carrying out heat treatment at a temperature of 40° C. or higher and 65° C. or lower.

7. A process for producing an ink jet recording head according to claim 1, wherein the first heat treatment is carried out under a reduced pressure.

8. A process for producing an ink jet recording head according to claim 1, wherein the multifunctional epoxy resin (A) is at least one of compounds represented by the following structural formulae (3) to (7): 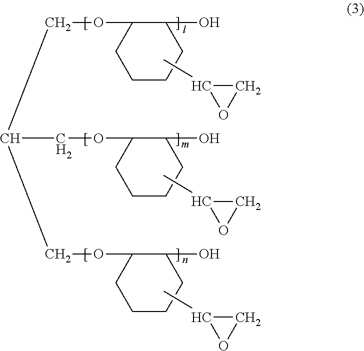
in the structural formula (3), l, m, and n are positive integers; 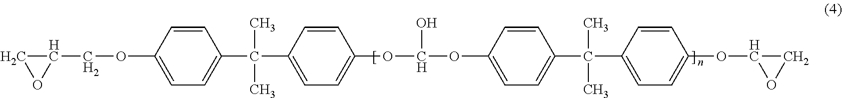
in the structural formula (4), n is a positive integer; 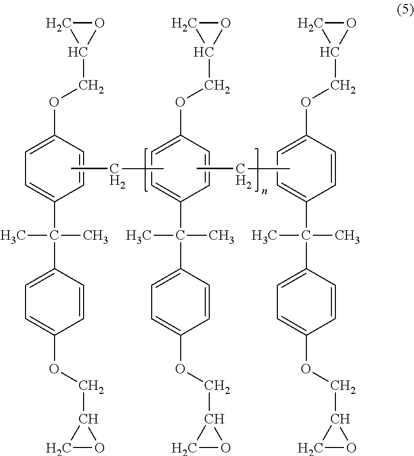
in the structural formula (5), n is a positive integer; 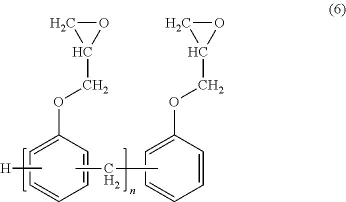
in the structural formula (6), n is a positive integer; and 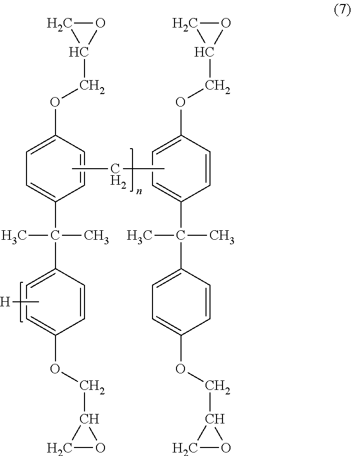
in the structural formula (7), n is a positive integer.
